(19) United States
(12) Patent Application Publication
(10) Pub. No.: US 2025/0029948 A1
(43) Pub. Date: Jan. 23, 2025

(54) Reducing warpage in a package of stacked integrated circuit dies

(71) Applicant: Marvell Asia Pte Ltd, Singapore (SG)

(72) Inventor: Runzi Chang, Saratoga, CA (US)

(21) Appl. No.: 18/776,419

(22) Filed: Jul. 18, 2024

Related U.S. Application Data
(60) Provisional application No. 63/527,818, filed on Jul. 19, 2023.

(51) Int. Cl. H01L 23/00; H01L 21/02; H01L 25/065; H10B 80/00

(52) U.S. Cl. CPC H01L 24/32; H01L 21/02118; H01L 24/08; H01L 24/27; H01L 24/29; H01L 25/0657; H01L 2224/0801; H01L 2224/08112; H01L 2224/27848; H01L 2224/29019; H01L 2224/32225; H01L 2225/06524; H01L 2924/1437; H01L 2924/3511; H10B 80/00

(57) ABSTRACT

An electronic device includes (i) a substrate having a first coefficient of thermal expansion (CTE), (ii) an integrated circuit (IC) die formed on the substrate and including first metal layers having a first thickness, and second metal layers having a second thickness, greater than the first thickness, the second metal layers have a second CTE, greater than the first CTE, the first and second metal layers are configured to induce, in response to an increase in a temperature of the electronic device, a first stress that acts to cause a warpage at least in the substrate, and (iii) a dielectric layer having a third CTE less than the first and second CTEs, is (a) disposed on the second metal layers, and (b) configured to induce at least in the substrate, in response to the increase in the temperature, a second stress that compensates for at least part of the warpage.

### CROSS-REFERENCE TO RELATED APPLICATIONS

This application claims the benefit of U.S. Provisional Patent Application 63/527,818, filed Jul. 19, 2023, whose disclosure is incorporated herein by reference.

### FIELD OF THE DISCLOSURE

The present invention relates generally to packaging of electronic devices, and particularly to methods and systems for reducing warpage in a package of an integrated circuit (IC) die and in stacked IC dies or chiplets in an electronic device.

### BACKGROUND

Integrated circuit (IC) dies typically comprise devices (e.g., transistors, diodes, and capacitors) formed in a semiconductor (e.g., silicon) substrate, and multiple levels (e.g., between 15 and 30) of metal layers and dielectric layers for routing signals to and from the devices formed in the substrate. Each of the above materials (semiconductor, dielectric, and metal) has a different coefficient of thermal expansion (CTE), for example, the CTEs of copper, silicon wafer, and silicon dioxide in ppm/° C. are about 17, 2.6, and 0.24, respectively. In other words, there is a big difference (e.g., of one or more orders of magnitude) between the CTEs of the materials in the IC die. Moreover, IC dies are required to operate at a broad range of temperatures, for example, between about between −40° C. and 150° C. As such, in response to temperature changes, the IC die may become warped due to the difference in CTEs. The warpage (also referred to herein as distortion) in the IC die may impair the electronic performance of the IC die.

Some electronic devices comprise vertical stacking and packaging of a plurality of IC dies. As such, the aforementioned warpage is one or more of the stacked IC dies, may worsen the distortion problem and the impairment in the electronic performance of the packaged electronic device. Moreover, some of the stacked IC dies may require an increased thickness of the uppermost levels metal layers, which may exacerbate warpage. While reducing the thickness of the uppermost levels of metal layers can mitigate the warpage problem, it may increase voltage drop (also referred to herein as IR drop), and thereby may impair electronic performance of the electronic device.

The description above is presented as a general overview of related art in this field and should not be construed as an admission that any of the information it contains constitutes prior art against the present patent application.

### SUMMARY

An embodiment of the present invention that is described herein provides an electronic device including (i) a substrate having a first coefficient of thermal expansion (CTE), (ii) an integrated circuit (IC) die formed on the substrate, the IC die including one or more first metal layers having a first thickness, and a plurality of second metal layers having a second thickness, greater than the first thickness, at least one of the second metal layers has a second CTE, greater than the first CTE, the first and second metal layers are configured to induce, in response to an increase in a temperature of the electronic device, a first stress that acts to cause a warpage at least in the substrate, and (iii) a dielectric layer, which is disposed on one of the second metal layers, the dielectric layer having a third CTE less than the first and second CTEs, the dielectric layer being configured to induce at least in the substrate, in response to the increase in the temperature, a second stress that compensates for at least part of the warpage.

In some embodiments, in response to the increased temperature, at least one of the second metal layers is configured to apply a tensile stress to the electronic device, and the dielectric layer is configured to apply a compressive stress to the electronic device, to compensate at least part for the tensile stress. In other embodiments, the plurality of second metal layers includes (i) an inner second metal layer disposed on one of the first metal layers, and (ii) an outer second metal layer disposed on the inner second metal layer, and at least the outer second metal layer is patterned with openings. In yet other embodiments, the dielectric layer includes tetraethyl orthosilicate (TEOS), which is disposed in the openings over the inner second metal layer.

In some embodiments, the dielectric layer includes polyimide disposed over the outer second metal layer, and the polyimide of the dielectric layer is cured by optical radiation to reduce the third CTE. In other embodiments, the optical radiation includes ultraviolet (UV) radiation, and in response to applying the UV radiation, a stiffness of the dielectric layer increases to compensate for at least part of the first warpage. In yet other embodiments, the dielectric layer has additional openings configured to receive an electrically conductive layer for electrical coupling between the outer second metal layer and a device out of the IC die.

In some embodiments, the first thickness is smaller than 1 micrometer, and the second thickness is larger than 1 micrometer. In other embodiments, the first stress acts to cause the warpage biased to have a concave shape, and the second stress acts to cause an additional warpage biased to have a convex shape that is at least partially opposite of the concave shape.

There is additionally provided, in accordance with an embodiment of the present invention, a method for fabricating an electronic device, the method including disposing, on a substrate having a first coefficient of thermal expansion (CTE), an integrated circuit (IC) die formed on the substrate, the IC die including one or more first metal layers having a first thickness. A plurality of second metal layers having a second thickness, greater than the first thickness, is disposed on one of the first metal layers, at least one of the second metal layers has a second CTE, greater than the first CTE, and in response to an increase in a temperature of the electronic device, the first and second metal layers induce a first stress that acts to cause a warpage at least in the substrate. A dielectric layer having a third CTE less than the first and second CTEs, is disposed on one of the second metal layers, and in response to the increase in the temperature, the dielectric layer induces, at least in the substrate, a second stress that compensates for at least part of the warpage.

There is further provided, in accordance with an embodiment of the present invention, a method for semiconductor device fabrication, the method including mounting, on a first carrier substrate, a semiconductor device including: (i) a substrate having a first coefficient of thermal expansion (CTE), and an integrated circuit (IC) die formed on the substrate, the IC die including at least a first metal layer having a first thickness, and at least a second metal layer, which is formed over the first metal layer, the second metal layer having (i) a second thickness, larger than the first thickness, and (ii) a second CTE, larger than the first CTE. A second carrier substrate is placed on the second metal layer. The first carrier substrate is mounted on an electrostatic chuck, and mechanical force is applied to the second carrier substrate for flattening the semiconductor device. A thermal treatment is applied to at least the semiconductor device for reducing warpage in the semiconductor device.

In some embodiments, mounting the semiconductor device on the first carrier substrate includes mounting the semiconductor device on a first silicon carrier substrate, and placing the second carrier substrate on the second metal layer includes placing (i) a second silicon carrier substrate or (ii) a glass carrier substrate, on the second metal layer.

The present disclosure will be more fully understood from the following detailed description of the embodiments thereof, taken together with the drawings in which:

### BRIEF DESCRIPTION OF THE DRAWINGS

FIG. 1-3 are schematic, sectional views of process operations for reducing warpage in electronic devices, in accordance with a embodiment that is described herein; and

FIG. 4 is a flow chart that schematically illustrates a method for reducing warpage in the IC die of FIG. 3, in accordance with an embodiment that is described herein.

### DETAILED DESCRIPTION OF EMBODIMENTS

Embodiments of the present disclosure that are described herein provide techniques for mitigating warpage in electronic devices comprising multiple integrated circuit (IC) dies or chiplets packaged in a vertical stack. In the context of the present disclosure and in the claims, the term chiplet refers to an IC, which is formed by partitioning a semiconductor-based IC die and contains a well-defined subset of functionality.

In the present example, the electronic device comprises a static random-access memory (SRAM) chiplet intended to be stacked on a processor chiplet, but the techniques described herein are also applicable to (i) stacking and packaging IC dies, and (ii) packaging a single IC die. Thus, in the description below, the term SRAM device, refers to either a SRAM chiplet or a SRAM IC die.

In some embodiments, SRAM chiplets or SRAM IC dies typically comprise memory cells formed in a silicon substrate, and between about 15 and 20 levels of metal layers formed in patterned dielectric layers, which are disposed on the silicon substrate for routing signals to and from the memory cells of the SRAM device. The two uppermost levels of metal layers may have (i) a regular thickness, similar to the thickness of at least one of the other levels of metal layers (e.g., between about 0.8 μm and 0.9 μm) such layers are referred to herein as 2 Mz, or (ii) an increased thickness (e.g., between about 1.1 μm and 1.2 μm or thicker) such layers are referred to herein as 2 Mr.

As described above, the IC die may become distorted due to changes in the temperature of the electronic device. While using 2 Mz in the SRAM device could reduce the warpage, it may also increase the voltage drop in electrical signals conducted in the IC die, and thereby reduce the electronic performance of the electronic device.

In the context of the present disclosure and in the claims, the terms distorted, warped, and grammatical variations thereof are used interchangeably.

In some embodiments, the SRAM device comprises a silicon substrate having a CTE of about 2.6 ppm/° C., and first and second groups of metal layers (e.g., copper layers) patterned in dielectric layers (e.g., silicon dioxide layers) for conducting the signals to and from the SRAM memory cells. The first metal layers have a thickness smaller than about 1 μm, and the second metal layers comprise the 2 Mr, e.g., the uppermost metal layers having an increased thickness, e.g., between about 1.1 μm and 1.2 μm or any other suitable thickness. In the present example, the CTE of the first and second metal (e.g., copper) layers is about 17 ppm/° C. but if using a metal other than copper, the CTE could be between about 10 ppm/° C. and 30 ppm/° C.

In some embodiments, the second metal layers (also referred to herein as the Mr layers) comprise an inner second metal layer disposed on one of the first metal layers, and an outer second metal layer disposed on the inner second metal layer. In some embodiments, the dielectric layers of the SRAM device may comprise several types of dielectric layers having different properties, which are described below.

In some embodiments, one of the dielectric layers is formed on the inner second metal layer, and is patterned with openings (e.g., trenches) intended to receive the outer second metal layer. In the present example, the dielectric layer is engineered by process conditions and thickness to have a CTE between about 0.1 ppm/° C. and 0.5 ppm/° C. For example, the dielectric layer may comprise thermal oxide. Additionally, or alternatively, process parameters of a chemical vapor deposition (CVD) process may be tuned to fabricate oxide layers (e.g., fused silica) having CTE less than about 0.5 ppm/° C. It is noted that the CTE (between about 0.1 ppm/° C. and 0.5 ppm/° C.) of the engineered dielectric layer is (i) less than the CTE of the silicon substrate by an order of magnitude, and (ii) less than the CTE of the copper layers by two orders of magnitude. In such embodiments, in response to an increase in the temperature of the SRAM device, the first and second metal layers being configured to induce a first stress that acts to cause a warpage at least in the substrate of the SRAM device (and in some cases across the entire SRAM device). In the present example, the warpage is biased to have a concave shape. Moreover, in response to the increase in the temperature, the dielectric layer being configured to induce at least in the substrate (and typically across the SRAM device), a second stress, opposite of the first stress, which compensates for at least part of the warpage.

In some embodiments, the first stress comprises a tensile stress and the second stress comprises a compressive stress. In the present example, the compressive stress acts to cause an additional warpage biased to have a convex shape that is at least partially opposite of the concave shape.

As such, in response to the increased temperature, at least the 2 Mr are configured to apply the tensile stress to the SRAM device, and the dielectric layer is configured to apply the compressive stress to the SRAM device, so as to compensate for at least part of the tensile stress applied by the 2 Mr.

In some embodiments, the dielectric layer may comprises Si(OC₂H₅)₄, also referred to herein as tetraethyl orthosilicate (TEOS). In some embodiments, the TEOS layer may be deposited using an organometallic based plasma enhanced chemical vapor deposition (PECVD). Moreover, some process parameters, such as but not limited to temperature, power, pressure, and stoichiometry of the TEOS layer, may be adjusted to obtain the compressive stress applied by the TEOS layer as described above. Due to the compressive stress applied (at least to the substrate) by the TEOS layer, the IC die is warped and biased toward a convex shape. Subsequently, the TEOS layer is patterned with multiple openings (e.g., trenches) and the outer 2 Mr layer is disposed in the openings. As described above, in response to athe increase in the temperature of the IC die, the 2 Mr layers apply a tensile stress to at least the substrate of the IC die. The tensile stress induces at least in the substrate (and typically in the entire structure of the IC die) the concave-shaped warpage. It is noted that the concave-shaped warpage compensates for the convex-shaped warpage caused by the TEOS of the dielectric layer. The convex shape warpage and the concave shape warpage cancel each other (at least partially) and improve the flatness of the IC die.

In other embodiments, the SRAM device may comprise an additional dielectric layer made from polyimide, which is cured (e.g., by applying ultraviolet radiation to the polyimide) to increase the stiffness and to reduce the CTE of the additional dielectric layer. Both techniques for mitigating the warpage in (i) the SRAM devices, and (ii) stacked IC dies or stacked chiplets comprising an SRAM chiplet, are described in detail with reference to FIGS. 2 and 3 below.

In other embodiments, the warpage mitigation may be carried out without using dielectric layers configured to induce forces that act to cause a predefined warpage, such as the TEOS-based dielectric layer and/or the cured polyimide-based dielectric layer described above. In such embodiments, the SRAM device having the 2 Mr may be confined between two carriers made from silicon or made from glass. For example, the silicon substrate may be mounted on a first carrier, which is made from silicon, and the outer Mr layer may be coupled to a second carrier made from silicon or from glass.

In some embodiments, the first carrier is placed on an electrostatic chuck configured to flatten the first carrier. Moreover, while flattening the first carrier and the silicon substrate, a uniform mechanical force is applied to the second carrier for flattening (and reducing warpage in) the second carrier, and particularly, in the 2 Mr layers.

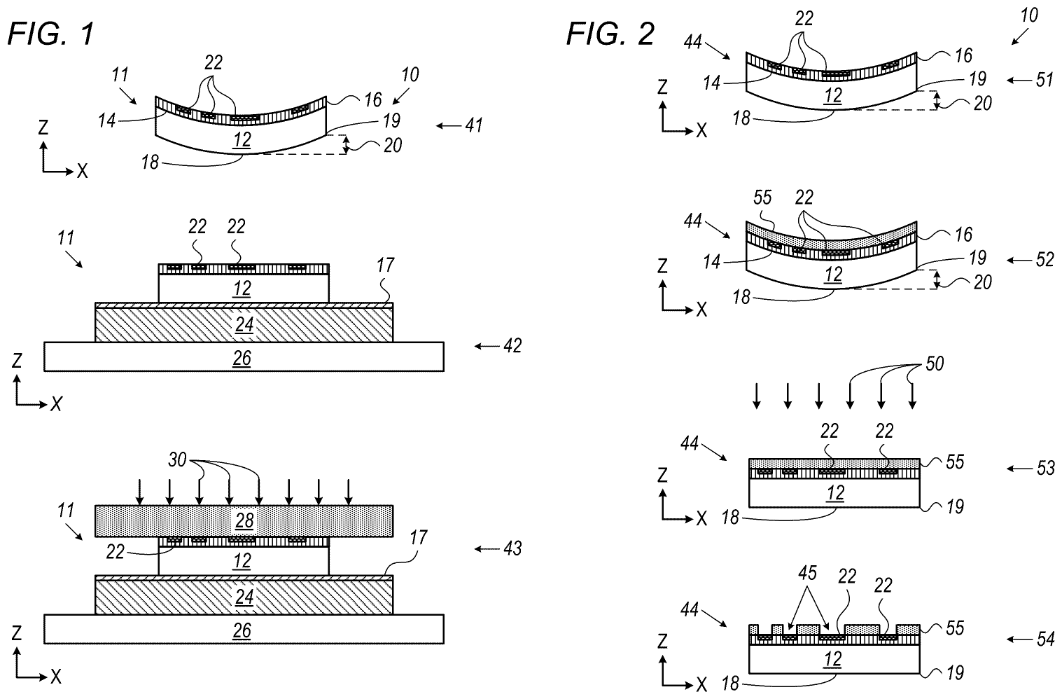

In some embodiments, after flattening both sides of the SRAM devices held between (i) the first carrier and the electrostatic chuck, and (ii) the second carrier on which the mechanical force is applied, a thermal treatment is applied to the SRAM device for the purpose of annealing the SRAM device. In the thermal annealing process, which is carried out simultaneously with the application of the electrostatic-based force (applied via the first carrier) and the uniform mechanical force (applied via the second carrier), the substrate and the layers of the SRAM device align relative to one another to reduce the internal warpage and improve the flatness of the SRAM device. The flattening technique using a combination of applying (i) external mechanical forces at both sides of the SRAM device and (ii) thermal treatment (e.g., annealing), is described in detail in FIG. 1 below.

The description above is presented as a general overview of embodiments of the present disclosure, which are described in detail herein.

FIG. 1 is a schematic, sectional view of process operations 41, 42 and 43 for reducing warpage in an electronic device 10, in accordance with an embodiment that is described herein.

In some embodiments, electronic device 10 comprises one or more IC dies and/or chiplets. As such, electronic device 10 may comprise a plurality of IC dies and/or chiplets (both not shown) stacked along a Z-axis of the XZ coordinate system, or a single IC die (as shown in the present example). In the example of stacked chiplets, electronic device 10 may comprise a static random-access memory (SRAM) chiplet stacked on a processor chiplet. This configuration can be used as a cost-effective alternative to an application-specific integrated circuit (ASIC) having the processing and SRAM functions integrated in a single IC die. For the sake of conceptual clarity, the mitigation of warpage is presented on a single IC die, but the embodiments of the present disclosure described below are also applicable to packaging of electronic devices using 3DIC techniques known in the art, such as packaging (i) a stack of chiplets, (ii) a stack or IC dies, and (iii) a stack of a suitable combination of chiplets and IC dies.

In some embodiments, electronic device 10 comprises a static random-access memory (SRAM) IC die 11 having (i) memory cells formed in a surface 14 of a semiconductor (e.g., silicon) substrate 12, and (ii) a plurality of metal layers 16 and 22 patterned in dielectric layers (e.g., silicon dioxide layers—not shown) and configured to conduct electrical signals to and from the SRAM memory cells. It is noted that the dielectric layers are configured to electrically insulate between patterns within a metal layer and between adjacent metal layers. In the present example, IC die 11 comprises about twelve (or any other suitable number of) levels of metal layers 16, and about two levels of metal layers 22.

In other embodiments, electronic device 10 may comprise a SRAM chiplet (instead of IC die 11) intended to be stacked on a processor chiplet (not shown). It is noted that the choice of presenting the disclosed techniques to reduce warpage in a single IC die 11 is made for the sake of conceptual clarity.

In some embodiments, the first level of metal layers 16 is patterned in a first dielectric layer (not shown) formed on surface 14. Moreover, IC die 11 comprises electrically conductive vias (not shown) for electrically connecting between the first level of metal layers 16 and the transistors of the SRAM memory cells.

In some embodiments, a second dielectric layer (not shown) is formed on the first dielectric layer, and is patterned with openings (e.g., trenches and holes), and the second level of metal layers 16 is disposed into the openings in the second dielectric layer. Moreover, the second level of metal layers 16 may fill the holes to constitute the vias for electrically connecting between the first and second levels of the metal layers 16. Similarly, the other ten levels of metal layers 16 are patterned in respective dielectric layers, stacked over one another and interconnected by electrically conductive vias. In the present example, the thickness of metal layers 16 increases gradually from the first level toward the twelfth level, but even the thickest metal layers 16 has a thickness (along the Z-axis) smaller than about 1 μm, e.g., between about 0.8 μm and 0.9 μm.

In some embodiments, metal layers 22 are arranged in (i) a first level of metal layer 22 disposed in openings patterned in a given dielectric layer (not shown), which is formed on the twelfth metal layer 16, and (ii) a second level of metal layer 22 is similarly formed in opening of another dielectric layer (not shown), which is formed on the given dielectric layer. It is noted that electrically conductive vias are formed between adjacent levels of metal layers 16 and 22, the vias and metal layers are configured to route the electrical signals to and from the memory cells formed in substrate 12 of the SRAM IC die 11.

In some embodiments, the second level of metal layer 22 is the outer conductive layer of IC die 11. In the present example, the thickness of metal layers 22 is larger than about 1 μm, e.g., between about 1.1 μm and 1.2 μm, or even thicker than 1.2 μm. It is noted that the increased thickness of metal layer 22 (e.g., to 1.2 μm) (i) reduces the electrical resistance of the metal layers, and thereby, reduces the voltage drop and improves electrical performance of IC die 11, and (ii) enables a reduction in the width of metal layers 22 (e.g., along the X-axis) to enable scaling (e.g., increasing the performance and/or reducing the footprint) of IC die 11.

In some embodiments, IC die 11 comprises a mix of materials, each material having a different coefficient of thermal expansion (CTE). For example, the CTE of copper (of the metal layers 16 and 22) is about 17 ppm/° C., and the CTE of silicon (of substrate 12) is about 2.6 ppm/° C., i.e., smaller than that of copper by an order of magnitude. Moreover, the typical CTE of the dielectric layers is less than 1 ppm/° C., which is smaller than the CTE of the copper by two orders of magnitude.

Reference is now made to operation 41. Electronic device 10 is required to operate at a broad range of temperatures, for example, between −40° C. and 150° C. At high temperatures (e.g., higher than about 90° C.), the increased thickness of metal layers 22, and the CTE difference between copper and silicon, induce forces that act to cause a warpage 20 of IC die 11. In the present example, warpage 20 is measured by the difference in the position between the center 18 and the edge 19 of IC die 11 along the Z-axis. In some embodiments, the magnitude of warpage 20 may be reduced by reducing the thickness of metal layers 22, for example, from about 1.2 μm to about 0.8 μm, but the reduced thickness results in an undesired increase in (i) the electrical resistance and voltage drop, and (ii) the footprint of IC die 11, as described above. In the context of the present disclosure, metal layers 22 having (i) a submicron thickness (e.g., between about 0.8 μm and 0.9 μm) are referred to herein as 2 Mz, or (ii) an increased thickness (e.g., between about 1.1 μm and 1.2 μm) are referred to herein as 2 Mr.

In some embodiments, a technique to reduce the warpage 20 in IC die 11 having the 2 Mr comprises placing and pressing IC die 11 between two carriers (described herein) made from silicon or made from glass, as will be described in operations 42 and 43 below. Reference is now made to operation 42. In some embodiments, substrate 12 is mounted on a carrier 24, both the substrate and the carrier are made from silicon. Substrate 12 is coupled to carrier 24 using a layer 17 of glue or another suitable material, and carrier 24 is placed on an electrostatic chuck 26 configured to flatten carrier 24 as shown in operation 42.

Reference is now made to operation 43. In some embodiments, a carrier 28 made from silicon or from glass is placed in contact with the outer metal layer 22. In the present example, outer metal layer 22 is placed beneath carrier 28, but in other embodiments, the stack of electrostatic chuck 26, carrier 24, IC die 11, and carrier 28 may be positioned up-side-down (relative to the position shown in operation 43), so that carrier 28 is placed beneath outer metal layer 22. In some embodiments, a uniform mechanical force 30 is applied to carrier 28 for flattening the metal layers 22 and the entire structure of IC die 11. It is noted that the application of the (i) electrostatic force (in operation 42) and (ii) mechanical force (in operation 43) are carried out simultaneously for at least a predefined time interval.

In some embodiments, during the time interval, a thermal treatment is applied to IC die 11 for the purpose of annealing crystalline defects (e.g., voids and dislocations) occurred, due to warpage 20, in substrate 12 and/or in the metal and dielectric layers of IC die 11. In the thermal annealing process that is carried out simultaneously with the application of the electrostatic force (applied by electrostatic chuck 26) and mechanical force 30 applied to carrier 28, the substrate 12 and the metal and dielectric layers of IC die 11 align relative to one another to reduce the internal warpage, and thereby, improve the flatness of IC die 11. In other words, the technique for reducing warpage 20 is carried out using a combination of applying (i) external mechanical force via carriers 24 and 28, and (ii) a thermal treatment, such as annealing.

In some embodiments, the annealing process increases the temperature gradually (e.g., linearly) to about 400° C. for a predefined time interval (e.g., between about 1 hour and 24 hours), and subsequently, reduces the temperature to room temperature (25° C.). In the present example, the rate of temperature increase is higher than the rate of temperature decrease, but in other embodiments, any suitable profile of temperatures may be used to carry out the annealing process. It is noted that the increase in temperature provides the atoms of the crystal lattice with energy to migrate within the lattice toward the crystalline defects, and thereby, to remove the voids and dislocations, and relieve stresses (e.g., tensile stress and/or compressive stress in metal layers 16 and 22 and/or in substrate 12).

In alternative embodiments, by using altered process conditions, the metal layers 16 and 22 are configured to apply compressive stress, and substrate 12 is configured to apply tensile stress.

These particular techniques for reducing warpage in SRAM-based IC die 11 of electronic device 10 is shown by way of example, in order to illustrate certain problems that are addressed by embodiments of the present invention and to demonstrate the application of these embodiments in reducing the warpage and enhancing the performance of such an electronic device. Embodiments of the present invention, however, are by no means limited to this specific sort of example electronic device 10 and/or IC die 11, and the principles described herein may similarly be applied to other sorts of electronic devices, such as an electronic device comprising a stack of chiplets as described above.

FIG. 2 is a schematic, sectional view of process operations 51, 52, 53 and 54 for reducing warpage in an IC die 44 of electronic device 10, in accordance with an embodiment that is described herein.

Reference is now made to operation 51. In some embodiments, in the example of operation 51, the configuration of IC die 44 is similar to that of IC die 11 described in FIG. 1 above. As such, the increased temperature in IC die 44 induces tensile forces and/or compressive forces that act to cause warpage 20, as described in detail in FIG. 1 above.

Reference is now made to operation 52. In some embodiments, a layer 55 of polyimide having a thickness between about 1 μm and 10 μm is formed over the outer level of metal layer 22, which is patterned in a respective dielectric layer as described in detail in FIG. 1 above.

Reference is now made to operation 53. In some embodiments, the polyimide of layer 55 is photosensitive, in the present example, in response to exposure to an optical radiation, such as an ultraviolet (UV) light 50 for a predefined time interval (e.g., a few seconds or less), spectrum and intensity, the stiffness of layer 55 is increased and the CTE of layer 55 is reduced. In other embodiments, other properties of layer 55 may be altered in response to exposing layer 55 to any other suitable wavelength of light, which can be optical or other than optical.

In such embodiments, in response to applying the UV light 50, layer 55 is configured to compensate for the stress applied to IC die 44 by metal layers 26. In other words, after UV curing, layer 55 serves as a stress buffer to compensate for at least part of the stress induced in high temperatures by metal layers 22, which acts to cause warpage 20, as described in FIG. 1 above. In the present example, in response to the increased temperature, at least metal layers 22 are configured to apply a tensile stress to IC die 44, and layer 55 is configured to apply to IC die 44 a compressive stress, so as to compensate for at least part of the tensile stress. It is noted that no hard bake of layer 55 is required.

In some embodiments, the compressive stress applied to IC die 44 by layer 55 may act to cause another warpage of IC die 44, typically in an opposite direction to the of warpage 20. In other words, the tensile force applied by the metal layers 22 acts to cause warpage 20 biased toward a concave shape, and after being exposed to the UV light 50, layer 55 is configured to apply compressive stress to IC die 44 that acts to cause a warpage biased towards a convex shape. As such, the convex-shaped warpage compensates for at least part of the concave-shaped warpage 20, resulting in mitigating warpage 20 as shown in operation 53. In other words, the compressive stress compensates for at least part of the tensile stress, and thereby acts to reduce at least part of warpage 20. It is noted that in operation 53, layer 55 is not patterned during the UV curing process and has a solid (un-patterned) shape.

Reference is now made to operation 54. In some embodiments, after reducing at least part of warpage 20, layer 55 is patterned with openings 45 (e.g., using any suitable lithography and etching processes) to open electrical connections between the outer metal layer 22 and a device (not shown) out of IC die 44. In other words, openings 45 are configured to receive an electrically conductive layer (not shown) for electrically coupling between the outer metal layer 22 and another device out of IC die 44. For example, the other device may comprise a chiplet stacked on layer 55 and having conductive vias formed within openings 45 for electrically coupling between outer metal layer 22 and the chiplet.

FIG. 3 is a schematic, sectional view of process operations 61, 62 and 63 for reducing warpage in an IC die 88, in accordance with an alternative embodiment that is described herein. IC die 88 may replace IC die 11 or IC die 44 of electronic device 10.

Reference is now made to operation 61. In some embodiments, IC die 88 comprises substrate 12, SRAM memory cells (not shown), and metal layers 16 patterned in respective dielectric layers, as described in detail in FIG. 1 above.

In some embodiments, a dielectric layer 66 is disposed over metal layers 16. In the present example, dielectric layer 66 comprises Tetraethyl orthosilicate (TEOS). Moreover, some process parameters, such as but not limited to temperature, power, pressure, and stoichiometry of the TEOS layer, may be adjusted to obtain a compressive stress applied to at IC die 88 by (the TEOS) layer 66. Due to the compressive stress, IC die 88 has a convex-shaped warpage 60 (defined by the distance along the Z-axis between center 18 and edge 19 of substrate 12).

Reference is now made to operation 62. In some embodiments, TEOS layer 66 is patterned with multiple openings (e.g., trenches) 77 using any suitable patterning technique, e.g., using any suitable lithography and etching processes. It is noted that openings 77 have a depth of about 1.2 μm and are intended to receive metal layers 22 having a thickness of about 1.2 μm, as will be described in detail in operation 63 below. Moreover, it is noted that at least part of (and typically most of) warpage 60 remains in IC die 88 after the patterning of openings 77.

Reference is now made to operation 63. In some embodiments, metal layers 22 are disposed in openings 77 using any suitable metal deposition process, such as physical vapor deposition (PVD) followed by CVD and/or electroplating processes. Moreover, a chemical mechanical polishing (CMP) process is carried out after the deposition of metal layers 66 to remove residues of metal layers 66 from the outer surface 67 of TEOS layer 66.

In some embodiments, in response to an increase in the temperature of IC die 88, metal layers 22 apply a tensile stress to IC die 88, and generate a concave-shaped warpage, such as warpage 20 shown in FIGS. 1 and 2 above. It is noted that the combination of the convex shape and concave shape distortions compensate or balance for each other (at least partially) and improves the flatness of IC die 88, as shown in operation 63.

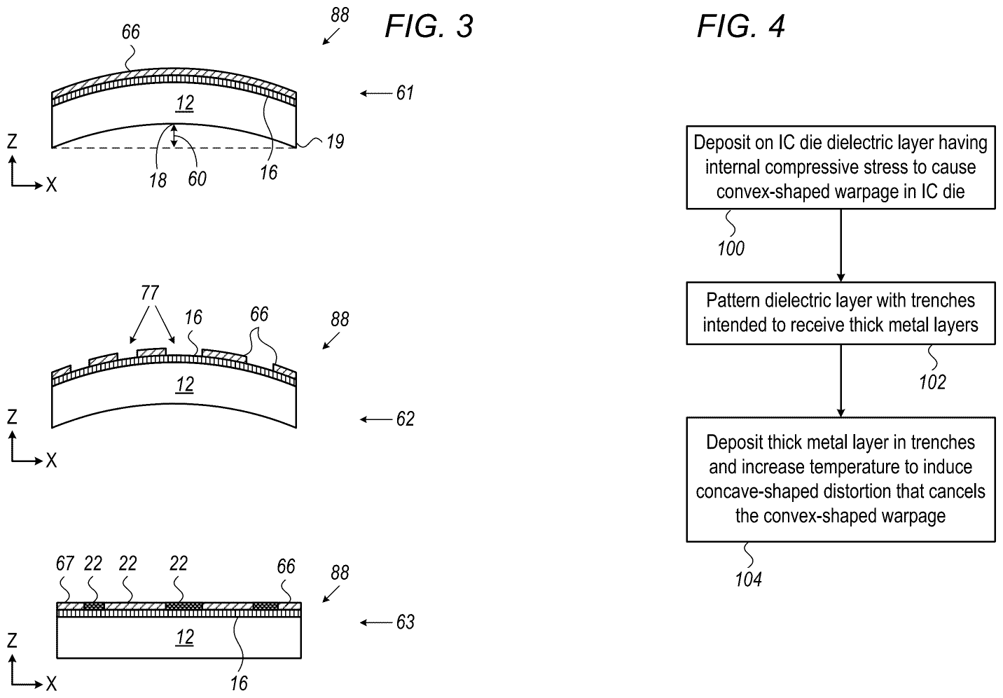

FIG. 4 is a flow chart that schematically illustrates a method for reducing warpage in IC die 88 of FIG. 3, in accordance with an embodiment that is described herein.

The method begins at a dielectric layer deposition operation 100, with disposing dielectric layer 66 over metal layer 16, and inducing compressive stress in layer 66 that acts to cause in IC die 88 convex-shaped warpage 60, as described in detail in operation 61 of FIG. 3 above.

At a patterning operation 102, dielectric layer 66 is patterned to form openings 77 having a depth of about 1.2 μm intended to receive metal layers 22 having a thickness of about 1.2 μm, as described in detail in operation 62 of FIG. 3 above.

At a metal deposition operation 104 that concludes the method, metal layers 22 are disposed in openings 77, and in response to the increase in the temperature of IC die 88, metal layers 22 apply a tensile stress to IC die 88 and induce the concave-shaped warpage 20 (shown in FIGS. 1 and 2 above). The combination of the convex shape and concave shape warpages compensate or balance for each other and improves the flatness of IC die 88, as described in detail in operation 63 of FIG. 3 above.

It is noted that the embodiments described above are cited by way of example, and that the present invention is not limited to what has been particularly shown and described hereinabove. Rather, the scope of the present invention includes both combinations and sub-combinations of the various features described hereinabove, as well as variations and modifications thereof which would occur to persons skilled in the art upon reading the foregoing description and which are not disclosed in the prior art. Documents incorporated by reference in the present patent application are to be considered an integral part of the application except that to the extent any terms are defined in these incorporated documents in a manner that conflicts with the definitions made explicitly or implicitly in the present specification, only the definitions in the present specification should be considered.

1. An electronic device, comprising:
a substrate having a first coefficient of thermal expansion (CTE);
an integrated circuit (IC) die formed on the substrate, the IC die comprising one or more first metal layers having a first thickness, and a plurality of second metal layers having a second thickness, greater than the first thickness, wherein at least one of the second metal layers has a second CTE, greater than the first CTE, the first and second metal layers are configured to induce, in response to an increase in a temperature of the electronic device, a first stress that acts to cause a warpage at least in the substrate; and
a dielectric layer, which is disposed on one of the second metal layers, the dielectric layer having a third CTE less than the first and second CTEs, the dielectric layer being configured to induce at least in the substrate, in response to the increase in the temperature, a second stress that compensates for at least part of the warpage.

2. The electronic device according to claim 1, wherein in response to the increased temperature, at least one of the second metal layers is configured to apply a tensile stress to the electronic device, and the dielectric layer is configured to apply a compressive stress to the electronic device, to compensate at least part for the tensile stress.

3. The electronic device according to claim 1, wherein the plurality of second metal layers comprises (i) an inner second metal layer disposed on one of the first metal layers, and (ii) an outer second metal layer disposed on the inner second metal layer, wherein at least the outer second metal layer is patterned with openings.

4. The electronic device according to claim 3, wherein the dielectric layer comprises tetraethyl orthosilicate (TEOS), which is disposed in the openings over the inner second metal layer.

5. The electronic device according to claim 3, wherein the dielectric layer comprises polyimide disposed over the outer second metal layer, and wherein the polyimide of the dielectric layer is cured by optical radiation to reduce the third CTE.

6. The electronic device according to claim 5, wherein the optical radiation comprises ultraviolet (UV) radiation, and wherein in response to applying the UV radiation, a stiffness of the dielectric layer increases to compensate for at least part of the first warpage.

7. The electronic device according to claim 5, wherein the dielectric layer has additional openings configured to receive an electrically conductive layer for electrically coupling between the outer second metal layer and a device out of the IC die.

8. The electronic device according to claim 1, wherein the first thickness is smaller than 1 micrometer, and the second thickness is larger than 1 micrometer.

9. The electronic device according to claim 1, wherein the first stress acts to cause the warpage biased to have a concave shape, and the second stress acts to cause an additional warpage biased to have a convex shape that is at least partially opposite of the concave shape.

10. A method for fabricating an electronic device, the method comprising:
disposing, on a substrate having a first coefficient of thermal expansion (CTE), an integrated circuit (IC) die formed on the substrate, the IC die comprising one or more first metal layers having a first thickness;
disposing, on one of the first metal layers, a plurality of second metal layers having a second thickness, greater than the first thickness, wherein at least one of the second metal layers has a second CTE, greater than the first CTE, in response to an increase in a temperature of the electronic device, the first and second metal layers induce a first stress that acts to cause a warpage at least in the substrate; and
disposing, on one of the second metal layers, a dielectric layer having a third CTE less than the first and second CTEs, in response to the increase in the temperature, the dielectric layer induces, at least in the substrate, a second stress that compensates for at least part of the warpage.

11. The method according to claim 10, wherein in response to the increased temperature, at least one of the second metal layers apply a tensile stress to the electronic device, and the dielectric layer applies a compressive stress to the electronic device, to compensate at least part for the tensile stress.

12. The method according to claim 10, wherein disposing the plurality of second metal layers comprises disposing: (i) an inner second metal layer on one of the first metal layers, and (ii) an outer second metal layer on the inner second metal layer, and comprising patterning at least the outer second metal layer with openings.

13. The method according to claim 12, wherein disposing the dielectric layer comprises disposing, in the openings over the inner second metal layer, tetraethyl orthosilicate (TEOS).

14. The method according to claim 12, wherein disposing the dielectric layer comprises disposing polyimide over the outer second metal layer and curing the polyimide by applying to the polyimide optical radiation to reduce the third CTE.

15. The method according to claim 14, wherein applying the optical radiation comprises applying ultraviolet (UV) radiation, and wherein in response to applying the UV radiation, a stiffness of the dielectric layer increases to compensate for at least part of the first warpage.

16. The method according to claim 14, further comprising forming in the dielectric layer additional openings for receiving an electrically conductive layer to electrically couple between the outer second metal layer and a device out of the IC die.

17. The method according to claim 10, wherein disposing the IC die comprises disposing (i) the first metal layers having the first thickness smaller than 1 micrometer, and (ii) the plurality of second metal layers having the second thickness larger than 1 micrometer.

18. The method according to claim 10, wherein disposing the plurality of second metal layers comprises inducing the first stress that acts to cause the warpage biased to have a concave shape, and disposing the dielectric layer comprises inducing the second stress to cause an additional warpage biased to have a convex shape that is at least partially opposite of the concave shape.

19. A method for semiconductor device fabrication, the method comprising:
mounting, on a first carrier substrate, a semiconductor device comprising: (i) a substrate having a first coefficient of thermal expansion (CTE), and an integrated circuit (IC) die formed on the substrate, the IC die comprising at least a first metal layer having a first thickness, and at least a second metal layer, which is formed over the first metal layer, the second metal layer having (i) a second thickness, larger than the first thickness, and (ii) a second CTE, larger than the first CTE;
placing a second carrier substrate on the second metal layer;
mounting the first carrier substrate on an electrostatic chuck, and applying mechanical force to the second carrier substrate for flattening the semiconductor device; and
applying a thermal treatment to at least the semiconductor device for reducing warpage in the semiconductor device.

20. The method according to claim 19, wherein mounting the semiconductor device on the first carrier substrate comprises mounting the semiconductor device on a first silicon carrier substrate, and wherein placing the second carrier substrate on the second metal layer comprises placing (i) a second silicon carrier substrate or (ii) a glass carrier substrate, on the second metal layer.
